(19) United States
(12) Patent Application Publication
(10) Pub. No.: US 2025/0113524 A1
(43) Pub. Date: Apr. 3, 2025

(54) NITRIDE STRUCTURE AND SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Ryoma KANEKO, Ota (JP); Hisashi YOSHIDA, Kawasaki (JP); Toshiki HIKOSAKA, Kawasaki (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/665,786

(22) Filed: May 16, 2024

(30) Foreign Application Priority Data
Oct. 3, 2023 (JP) 2023-172068

(51) Int. Cl. H01L 29/778; H01L 29/15; H01L 29/20

(52) U.S. Cl. CPC H10D 30/475; H10D 62/8181; H10D 62/8503

(57) ABSTRACT

According to one embodiment, a nitride structure includes a base, a nitride member, and a semiconductor member including Ga and N. The nitride member is provided between the base and the semiconductor member in a first direction. The nitride member includes a first nitride region, a second nitride region, and a third nitride region. The first nitride region is provided between the base and the third nitride region. The second nitride region is provided between the first nitride region and the third nitride region. The first nitride region includes AlN. The second nitride region includes Alₓ₂Ga₁₋ₓ₂N (0<x2<1). The third nitride region includes Alₓ₃Ga₁₋ₓ₃N (0<x3≤1, x2<x3). A second thickness of the second nitride region along the first direction is thinner than a third thickness of the third nitride region along the first direction.

### CROSS-REFERENCE TO RELATED APPLICATIONS

This application is based upon and claims the benefit of priority from Japanese Patent Application No. 2023-172068, filed on Oct. 3, 2023; the entire contents of which are incorporated herein by reference.

### FIELD

Embodiments described herein relate generally to a nitride structure and a semiconductor device.

### BACKGROUND

For example, improved characteristics are desired in semiconductor devices based on nitride structures.

### BRIEF DESCRIPTION OF THE DRAWINGS

FIG. 1 is a schematic cross-sectional view illustrating a nitride structure according to a first embodiment;

FIG. 2 is a schematic cross-sectional view illustrating a nitride structure according to the first embodiment;

FIG. 3 is a schematic cross-sectional view illustrating a nitride structure according to the first embodiment;

FIG. 4 is a schematic cross-sectional view illustrating a semiconductor device according to a second embodiment; and

FIG. 5 is a schematic cross-sectional view illustrating a semiconductor device according to the second embodiment.

### DETAILED DESCRIPTION

According to one embodiment, a nitride structure includes a base, a nitride member, and a semiconductor member including Ga and N. The nitride member is provided between the base and the semiconductor member in a first direction. The nitride member includes a first nitride region, a second nitride region, and a third nitride region. The first nitride region is provided between the base and the third nitride region. The second nitride region is provided between the first nitride region and the third nitride region. The first nitride region includes AlN. The second nitride region includes Alₓ₂Ga₁₋ₓ₂N (0<x2<1). The third nitride region includes Alₓ₃Ga₁₋ₓ₃N (0<x3≤1, x2<x3). A second thickness of the second nitride region along the first direction is thinner than a third thickness of the third nitride region along the first direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

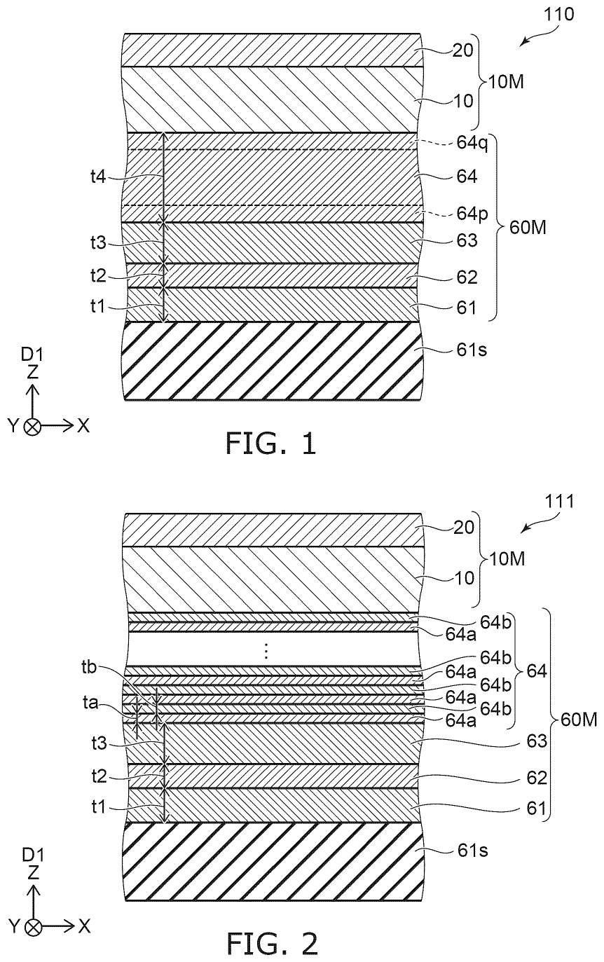

FIG. 1 is a schematic cross-sectional view illustrating a nitride structure according to a first embodiment.

As shown in FIG. 1, a nitride structure 110 according to the embodiment includes a base 61s, a nitride member 60M, and a semiconductor member 10M. The semiconductor member 10M includes Ga and N. The semiconductor member 10M may include at least one of GaN or AlGaN.

The nitride member 60M is provided between the base 61s and the semiconductor member 10M in a first direction D1. The first direction D1 is defined as a Z-axis direction. A direction perpendicular to the Z-axis direction is defined as an X-axis direction. A direction perpendicular to the X-axis direction and the Z-axis direction is defined as a Y-axis direction.

The nitride member 60M is layered along the X-Y plane. The semiconductor member 10M is layered along the X-Y plane.

The nitride member 60M includes a first nitride region 61, a second nitride region 62, and a third nitride region 63. The first nitride region 61 is provided between the base 61s and the third nitride region 63. The second nitride region 62 is provided between the first nitride region 61 and the third nitride region 63. The first nitride region 61, the second nitride region 62, and the third nitride region 63 are layered along the X-Y plane.

The first nitride region 61 includes AlN. The second nitride region 62 includes Alₓ₂Ga₁₋ₓ₂N (0<x2<1). The third nitride region 63 includes Alₓ₃Ga₁₋ₓ₃N (0<x3≤1, x2<x3). In one example, the composition ratio x2 is not less than 0.15 and less than 0.7. The composition ratio x3 is not more than 0.7 and not more than 1.

As shown in FIG. 1, a thickness of the second nitride region 62 along the first direction D1 is defined as a second thickness t2. A thickness of the third nitride region 63 along the first direction D1 is defined as a third thickness t3. In the embodiment, the second thickness t2 is thinner than the third thickness t3.

The nitride structure 110 is, for example, a nitride wafer. As described below, at least a part of the nitride structure 110 may be included in a semiconductor device. The semiconductor device may be, for example, a transistor. For example, the semiconductor member 10M functions as a functional layer in a semiconductor device. In a semiconductor device based on nitride structure 110, leakage current may occur. For example, leakage current reduces the breakdown voltage.

In the embodiment, the second nitride region 62 and third nitride region 63 described above are provided. Thereby, the leakage current can be suppressed. This provides high breakdown voltage. For example, by providing the second nitride region 62 and the third nitride region 63, carriers are suppressed from moving from the base 61s to the semiconductor member 10M. It is thought that this allows leakage current to be suppressed. It is considered that the second nitride region 62 and the third nitride region 63 function as carrier block layers, for example. According to the embodiment, a nitride structure with improved characteristics can be provided.

In the embodiment, the Al composition ratio in the second nitride region 62 is lower than the Al composition ratio in the third nitride region 63. For example, second nitride region 62 functions as a well layer. Third nitride region 63 functions as a barrier layer. In the embodiment, the third thickness t3 of the third nitride region 63 is thicker than the second thickness t2 of the second nitride region 62. This effectively suppresses carrier movement. The carrier is, for example, an electron.

The base 61s includes silicon, for example. The base 61s may be, for example, a silicon substrate. The nitride member 60M is, for example, a crystal. The semiconductor member 10M is, for example, a crystal.

As shown in FIG. 1, the first nitride region 61 may be in contact with the base 61s. The second nitride region 62 may be in contact with the first nitride region 61. The third nitride region 63 may be in contact with the second nitride region 62.

By providing the first nitride region 61 of AlN, for example, deterioration (for example, melt-back etching) of the base 61s is suppressed.

As shown in FIG. 1, a thickness of the first nitride region 61 along the first direction D1 is defined as a first thickness t1. In one example, the first thickness may be not less than 100 nm and not more than 300 nm. When the first thickness is 100 nm or more, for example, deterioration of the base 61s can be effectively suppressed. When the first thickness is 300 nm or less, for example, warping of the wafer can be suppressed.

In the embodiment, for example, the second thickness t2 may be thinner than the first thickness t1. For example, the third thickness t3 may be thicker than the first thickness t1. Such thickness relationship makes it easier to suppress the warpage of the wafer, for example.

In the embodiment, for example, the second thickness t2 is preferably not less than 10 nm and not more than 100 nm. when the second thickness t2 is 10 nm or more, for example, carriers are less likely to tunnel. For example, when the second thickness t2 is less than 100 nm, it is easy to confine carriers.

The third thickness t3 is preferably, for example, not less than 100 nm and not more than 300 nm. When the third thickness t3 is 100 nm or more, it is easy to effectively confine carriers in the second nitride region 62. For example, when the third thickness t3 is 300 nm or less, cracks are less likely to occur.

In one example, the first nitride region 61 does not include carbon. Alternatively, the concentration of carbon in the first nitride region 61 is lower than the concentration of carbon in the second nitride region 62. The high concentration of carbon in the second nitride region 62 makes it easier to suppress leakage current from the base 61s, for example.

In the embodiment, the Al composition ratio in the second nitride region 62 may be substantially constant. The Al composition ratio in the third nitride region 63 may be substantially constant. For example, the Al composition ratio changes stepwise between the first nitride region 61 and the second nitride region 62. For example, the composition ratio of Al changes stepwise between the second nitride region 62 and the third nitride region 63. Carrier movement is effectively blocked.

The second nitride region 62 and the third nitride region 63 may be included in one set. A plurality of the sets may be provided along the first direction D1. The number of the plurality of sets may be not less than 1 and not more than 3. By providing the plurality of sets, carrier movement can be suppressed more efficiently. Leakage current can be suppressed more effectively.

As shown in FIG. 1, the nitride member 60M may further include a fourth nitride region 64. The fourth nitride region 64 includes Al, Ga, and N. The fourth nitride region 64 is provided between the third nitride region 63 and the semiconductor member 10M.

In one example, the composition ratio of Al in the fourth nitride region 64 may change. As shown in FIG. 1, for example, the fourth nitride region 64 includes a first region 64p and a second region 64q. The second region 64q is provided between the first region 64p and the semiconductor member 10M. The Al composition ratio in the second region 64q is lower than the Al composition ratio in the first region 64p.

The Al composition ratio in the first region 64p is, for example, not less than 0.6 and less than 1. The Al composition ratio in the second region 64q is, for example, not less than 0.05 and not more than 0.2. The first region 64p may be in contact with the third nitride region 63, for example. The second region 64q may be in contact with the semiconductor member 10M, for example.

For example, the Al composition ratio in the fourth nitride region 64 may decrease in the direction from the third nitride region 63 to the semiconductor member 10M. The fourth nitride region 64 may be, for example, a layer with a gradient Al composition ratio. By providing the fourth nitride region 64 of the graded layer, stress caused by, for example, a difference in crystal lattice constants can be easily alleviated. For example, warping or cracking is suppressed.

The fourth nitride region 64 may be in contact with the third nitride region 63. The fourth nitride region 64 may be in contact with the semiconductor member 10M.

As shown in FIG. 1, a thickness of the fourth nitride region 64 along the first direction D1 is defined as a fourth thickness t4.

The fourth thickness t4 may be, for example, not less than 1 μm and not more than 5 μm.

As shown in FIG. 1, in this example, the semiconductor member 10M includes a first semiconductor region 10 and a second semiconductor region 20. The first semiconductor region 10 is provided between the nitride member 60M and the second semiconductor region 20. The first semiconductor region 10 includes Al_{z1}Ga_{1-z1}N (0≤z1<1). The first semiconductor region 10 includes, for example, GaN. The second semiconductor region includes Al_{z2}Ga_{1-z2}N (z1<z2<1). The second semiconductor region 20 includes, for example, AlGaN. The composition ratio z1 is, for example, not less than 0 and not more than 0.13. The composition ratio z2 is, for example, not less than 0.15 and not more than 0.35.

FIG. 2 is a schematic cross-sectional view illustrating a nitride structure according to the first embodiment.

As shown in FIG. 2, in a nitride structure 111 according to the embodiment, the configuration of the fourth nitride region 64 is different from the configuration of the fourth nitride region 64 in the nitride structure 110. The configuration of the nitride structure 111 except for this may be the same as the configuration of the nitride structure 110.

As shown in FIG. 2, in the nitride structure 111, the fourth nitride region 64 includes a plurality of first films 64a and a plurality of second films 64b. One of the plurality of first films 64a is provided between one of the plurality of second films 64b and another one of the plurality of second films 64b. One of the plurality of second films 64b is between one of the plurality of first films 64a and another one of the plurality of first films 64a. For example, the first film 64a and the second film 64b are provided alternately.

For example, the Al composition ratio in the plurality of first films 64a is higher than the Al composition ratio in the plurality of second films 64b. In the nitride structure 111, the fourth nitride region 64 is a superlattice layer. By providing such a fourth nitride region 64, for example, stress can be easily relaxed.

The first film thickness ta of each of the plurality of first films 64a is, for example, not less than 1 nm and less than 10 nm. The second film thickness tb of each of the plurality of second films 64b is, for example, not less than 10 nm and not more than 50 nm.

In the nitride structure 111, the average Al composition ratio in the fourth nitride region 64 may decrease in the direction from the third nitride region 63 to the semiconductor member 10M. For example, in the plurality of first films 64a, the Al composition ratio may decrease in the direction from the third nitride region 63 to the semiconductor member 10M. For example, in the plurality of first films 64a, the first film thickness ta may decrease in the direction from the third nitride region 63 to the semiconductor member 10M. For example, in the plurality of second films 64b, the second film thickness tb may increase in the direction from the third nitride region 63 to the semiconductor member 10M.

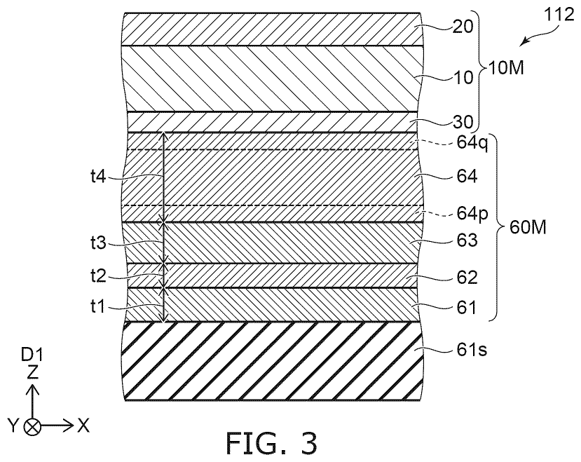

FIG. 3 is a schematic cross-sectional view illustrating a nitride structure according to the first embodiment.

As shown in FIG. 3, in a nitride structure 112 according to the embodiment, the configuration of the semiconductor member 10M is different from the configuration of the semiconductor member 10M in the nitride structure 110 or 111. The configuration of the nitride structure 112 except for this may be the same as the configuration of the nitride structure 110 or the nitride structure 111.

As shown in FIG. 3, in the nitride structure 112, the semiconductor member 10M further includes a third semiconductor region 30. The third semiconductor region 30 is provided between the nitride member 60M and the first semiconductor region 10. The third semiconductor region 30 includes Al_{z3}Ga_{1-z3}N (0≤z3<z2). The composition ratio z3 is, for example, not less than 0 and not more than 0.13. The third semiconductor region 30 includes, for example, GaN. The third semiconductor region 30 includes carbon. On the other hand, the first semiconductor region 10 does not include carbon. Alternatively, the concentration of carbon in the third semiconductor region 30 is higher than the concentration of carbon in the first semiconductor region 10. For example, the first semiconductor region 10 is i-GaN. By providing such a third semiconductor region 30, for example, higher crystal quality can be easily obtained. For example, carbon can compensate for carriers that cause leakage current. By providing the third semiconductor region 30 including carbon, for example, leakage current can be suppressed more effectively.

### Second Embodiment

The second embodiment relates to a semiconductor device. The semiconductor device according to the embodiment includes the nitride structure according to the first embodiment. An example in which a semiconductor device includes the nitride structure 110 will be described below. The semiconductor device may include the nitride structure 111 or the nitride structure 112.

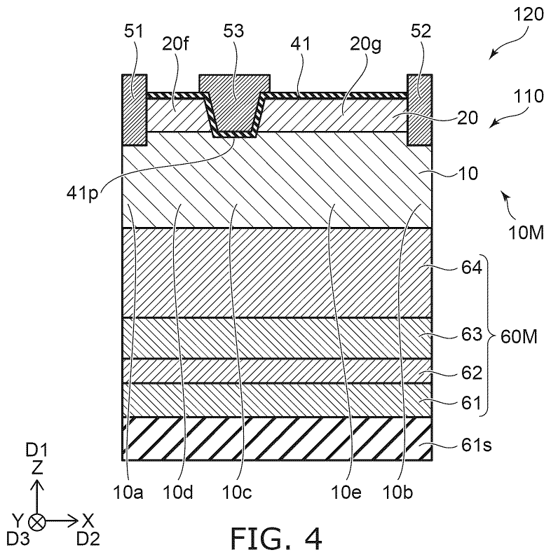

FIG. 4 is a schematic cross-sectional view illustrating a semiconductor device according to the second embodiment.

As shown in FIG. 4, a semiconductor device 120 according to the embodiment includes the nitride structure 110 according to the first embodiment, a first electrode 51, a second electrode 52, and a third electrode 53. The semiconductor device 120 may further include an insulating member 41.

A direction from the first electrode 51 to the second electrode 52 is along a second direction D2 crossing the first direction D1. The second direction D2 is, for example, the X-axis direction. A position of the third electrode 53 in the second direction D2 is between a position of the first electrode 51 in the second direction D2 and a position of the second electrode 52 in the second direction D2.

The semiconductor member 10M includes the first semiconductor region 10 and the second semiconductor region 20. The semiconductor member 10M may further include the third semiconductor region 30 (see FIG. 3).

The first semiconductor region 10 includes a first partial region 10a, a second partial region 10b, a third partial region 10c, a fourth partial region 10d, and a fifth partial region 10e. A direction from the first partial region 10a to the first electrode 51 is along the first direction D1. A direction from the second partial region 10b to the second electrode 52 is along the first direction D1. The third partial region 10c is located between the first partial region 10a and the second partial region 10b in the second direction D2. A direction from the third partial region 10c to the third electrode 53 is along the first direction D1. The fourth partial region 10d is located between the first partial region 10a and the third partial region 10c in the second direction D2. The fifth partial region 10e is located between the third partial region 10c and the second partial region 10b in the second direction D2.

The second semiconductor region 20 includes a sixth partial region 20f and a seventh partial region 20g. A direction from the fourth partial region 10d to the sixth partial region 20f is along the first direction D1. A direction from the fifth partial region 10e to the seventh partial region 20g is along the first direction D1.

For example, at least a part of the insulating member 41 is provided between the semiconductor member 10M and the third electrode 53. For example, the insulating member 41 includes a first insulating region 41p. The first insulating region 41p is provided between the third partial region 10c and the third electrode 53 in the first direction (Z-axis direction).

The first electrode 51 is electrically connected to the sixth partial region 20f. The second electrode 52 is electrically connected to the seventh partial region 20g. The first electrode 51, the second electrode 52, and the third electrode 53 may extend, for example, along a third direction D3. The third direction D3 crosses a plane including the first direction D1 and the second direction D2.

In the semiconductor device 120, current flowing between the first electrode 51 and the second electrode 52 can be controlled by a potential of the third electrode 53. The potential of the third electrode 53 is, for example, a potential based on the potential of the first electrode 51. The first electrode 51 functions, for example, as a source electrode. The second electrode 52 functions, for example, as a drain electrode. The third electrode 53 functions as, for example, a gate electrode. The semiconductor device 120 is, for example, a HEMT (High Electron Mobility Transistor).

According to the embodiment, leakage current is suppressed. For example, high breakdown voltage can be obtained. According to the embodiment, a semiconductor device with improved characteristics can be provided.

In the semiconductor device 120, at least a part of the third electrode 53 is provided between the sixth partial region 20f and the seventh partial region 20g in the second direction D2. At least a part of the third electrode 53 may be provided between the fourth partial region 10d and the fifth partial region 10e in the second direction D2. The first insulating region 41p may be provided between the fourth partial region 10d and the fifth partial region 10e. The semiconductor device 120 is, for example, a normally-off type.

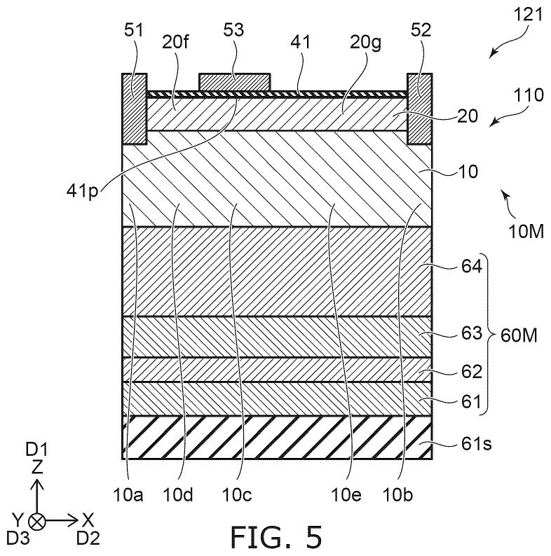

FIG. 5 is a schematic cross-sectional view illustrating a semiconductor device according to the second embodiment.

As shown in FIG. 5, a semiconductor device 121 according to the embodiment includes the nitride structure 110 according to the first embodiment, the first electrode 51, the second electrode 52, the third electrode 53, and the insulating member 41. In the semiconductor device 121, the third electrode 53 does not overlap the sixth partial region 20f and the seventh partial region 20g in the second direction D2. The third electrode 53 does not overlap the fourth partial region 10d and the fifth partial region 10e in the second direction D2. The semiconductor device 121 is, for example, a normally-on type. Leakage current can also be suppressed in the semiconductor device 121. A semiconductor device whose characteristics can be improved can be provided.

In the embodiment, information regarding the shape of the nitride region, etc. can be obtained, for example, by electron microscopic observation. Information regarding the composition and element concentration in the nitride region can be obtained by, for example, EDX (Energy Dispersive X-ray Spectroscopy) or SIMS (Secondary Ion Mass Spectrometry). Information regarding the composition in the nitride region may be obtained, for example, by X-ray reciprocal space mapping.

Embodiments may include the following technical proposals:

### Technical Proposal 1

A nitride structure, comprising:
a base;
a nitride member; and
a semiconductor member including Ga and N,
the nitride member being provided between the base and the semiconductor member in a first direction,
the nitride member including a first nitride region, a second nitride region, and a third nitride region,
the first nitride region being provided between the base and the third nitride region,
the second nitride region being provided between the first nitride region and the third nitride region,
the first nitride region including AlN,
the second nitride region including Alₓ₂Ga₁₋ₓ₂N (0<x2<1),
the third nitride region including Alₓ₃Ga₁₋ₓ₃N (0<x3≤1, x2<x3), and
a second thickness of the second nitride region along the first direction being thinner than a third thickness of the third nitride region along the first direction.

### Technical Proposal 2

The nitride structure according to Technical proposal 1, wherein
the first nitride region is in contact with the base,
the second nitride region is in contact with the first nitride region, and
the third nitride region is in contact with the second nitride region.

### Technical Proposal 3

The nitride structure according to Technical proposal 1, wherein
the second thickness is thinner than a first thickness of the first nitride region along the first direction.

### Technical Proposal 4

The nitride structure according to Technical proposal 3, wherein
the third thickness is thicker than the first thickness.

### Technical Proposal 5

The nitride structure according to Technical proposal 3 or 4, wherein
the first thickness is not less than 100 nm and not more than 300 nm.

### Technical Proposal 6

The nitride structure according to any one of Technical proposals 1-5, wherein
the second thickness is not less than 10 nm and less than 100 nm, and
the third thickness is not less than 100 nm and not more than 300 nm.

### Technical Proposal 7

The nitride structure according to any one of Technical proposals 1-6, wherein
the x2 is not less than 0.15 and less than 0.7, and
the x3 is not less than 0.7 and not more than 1.

### Technical Proposal 8

The nitride structure according to any one of Technical proposals 1-7, wherein
the nitride member further includes a fourth nitride region including Al, Ga, and N,
the fourth nitride region is provided between the third nitride region and the semiconductor member,
the fourth nitride region includes a first region and a second region,
the second region is provided between the first region and the semiconductor member, and
an Al composition ratio in the second region is lower than an Al composition ratio in the first region.

### Technical Proposal 9

The nitride structure according to Technical proposal 8, wherein
an Al composition ratio in the fourth nitride region decreases in a direction from the third nitride region toward the semiconductor member.

### Technical Proposal 10

The nitride structure according to Technical proposal 8 or 9, wherein
the fourth nitride region includes a plurality of first films and a plurality of second films,
one of the plurality of first films is provided between one of the plurality of second films and another one of the plurality of second films,
the one of the plurality of second films is provided between the one of the plurality of first films and another one of the plurality of first films, and
an Al composition ratio in the plurality of first films is higher than an Al composition ratio in the plurality of second films.

### Technical Proposal 11

The nitride structure according to any one of Technical proposals 1-7, wherein
the nitride member further includes a fourth nitride region including Al, Ga, and N,
the fourth nitride region is provided between the third nitride region and the semiconductor member,
the fourth nitride region includes a plurality of first films and a plurality of second films,
one of the plurality of first films is provided between one of the plurality of second films and another one of the plurality of second films,
the one of the plurality of second films is provided between the one of the plurality of first films and another one of the plurality of first films, and
an Al composition ratio in the plurality of first films is higher than an Al composition ratio in the plurality of second films.

### Technical Proposal 12

The nitride structure according to Technical proposal 10 or 11, wherein
a first film thickness of each of the plurality of first films is not less than 1 nm and less than 10 nm, and
a second film thickness of each of the plurality of second films is not less than 10 nm and not more than 50 nm.

### Technical Proposal 13

The nitride structure according to any one of Technical proposals 8-12, wherein
the fourth nitride region is in contact with the third nitride region.

### Technical Proposal 14

The nitride structure according to any one of Technical proposals 1-13, wherein
the base includes Si.

### Technical Proposal 15

The nitride structure according to any one of Technical proposals 1-14, wherein
the first nitride region does not include carbon, or a concentration of carbon in the first nitride region is lower than a concentration of carbon in the second nitride region.

### Technical Proposal 16

The nitride structure according to any one of Technical proposals 1-15, wherein
the semiconductor member includes a first semiconductor region and a second semiconductor region,
the first semiconductor region is provided between the nitride member and the second semiconductor region,
the first semiconductor region includes Al_{z1}Ga_{1-z1}N (0≤z1<1), and
the second semiconductor region includes Al_{z2}Ga_{1-z2}N (z1<z2<1).

### Technical Proposal 17

The nitride structure according to according to Technical proposal 16, wherein
the semiconductor member further includes a third semiconductor region,
the third semiconductor region is provided between the nitride member and the first semiconductor region,
the third semiconductor region includes Al_{z3}Ga_{1-z3}N (0≤z3<z2), and
the third semiconductor region includes carbon.

### Technical Proposal 18

A semiconductor device, comprising:
a nitride structure according to Technical proposal 16 or 17;
a first electrode;
a second electrode; and
a third electrode,
a direction from the first electrode to the second electrode being along a second direction crossing the first direction,
a position of the third electrode in the second direction being between a position of the first electrode in the second direction and a position of the second electrode in the second direction,
the first semiconductor region including a first partial region, a second partial region, a third partial region, a fourth partial region, and a fifth partial region,
a direction from the first partial region to the first electrode being along the first direction,
a direction from the second partial region to the second electrode being along the first direction,
the third partial region being between the first partial region and the second partial region in the second direction, and a direction from the third partial region to the third electrode being along the first direction,
the fourth partial region being between the first partial region and the third partial region in the second direction,
the fifth partial region being between the third partial region and the second partial region in the second direction,
the second semiconductor region including a sixth partial region and a seventh partial region,
a direction from the fourth partial region to the sixth partial region being along the first direction, and
a direction from the fifth partial region to the seventh partial region being along the first direction.

### Technical Proposal 19

The semiconductor device according to Technical proposal 18, further comprising:
an insulating member,
at least a part of the insulating member being provided between the semiconductor member and the third electrode.

### Technical Proposal 20

The semiconductor device according to Technical proposal 18 or 19, wherein
at least a part of the third electrode is provided between the sixth partial region and the seventh partial region in the second direction.

According to the embodiments, it is possible to provide a nitride structure and a semiconductor device with improved characteristics.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

In the specification, “state of being electrically connected” includes a state in which a plurality of conductors are physically in contact with each other and a current flows between the plurality of conductors. The “state of being electrically connected” includes a state in which another conductor is inserted between the plurality of conductors and a current flows between the plurality of conductors.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the nitride structure such as bases, nitride members, nitride regions, semiconductor members, semiconductor regions, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all nitride structures and all semiconductor devices practicable by an appropriate design modification by one skilled in the art based on the nitride structures and semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nitride structure, comprising:
a base;
a nitride member; and
a semiconductor member including Ga and N,
the nitride member being provided between the base and the semiconductor member in a first direction,
the nitride member including a first nitride region, a second nitride region, and a third nitride region,
the first nitride region being provided between the base and the third nitride region,
the second nitride region being provided between the first nitride region and the third nitride region,
the first nitride region including AlN,
the second nitride region including Alₓ₂Ga₁₋ₓ₂N (0<x2<1),
the third nitride region including Alₓ₃Ga₁₋ₓ₃N (0<x3≤1, x2<x3), and
a second thickness of the second nitride region along the first direction being thinner than a third thickness of the third nitride region along the first direction.

2. The structure according to claim 1, wherein
the first nitride region is in contact with the base,
the second nitride region is in contact with the first nitride region, and
the third nitride region is in contact with the second nitride region.

3. The structure according to claim 1, wherein
the second thickness is thinner than a first thickness of the first nitride region along the first direction.

4. The structure according to claim 3, wherein
the third thickness is thicker than the first thickness.

5. The structure according to claim 3, wherein
the first thickness is not less than 100 nm and not more than 300 nm.

6. The structure according to claim 1, wherein
the second thickness is not less than 10 nm and less than 100 nm, and
the third thickness is not less than 100 nm and not more than 300 nm.

7. The structure according to claim 1, wherein
the x2 is not less than 0.15 and less than 0.7, and
the x3 is not less than 0.7 and not more than 1.

8. The structure according to claim 1, wherein
the nitride member further includes a fourth nitride region including Al, Ga, and N,
the fourth nitride region is provided between the third nitride region and the semiconductor member,
the fourth nitride region includes a first region and a second region,
the second region is provided between the first region and the semiconductor member, and
an Al composition ratio in the second region is lower than an Al composition ratio in the first region.

9. The structure according to claim 8, wherein
an Al composition ratio in the fourth nitride region decreases in a direction from the third nitride region toward the semiconductor member.

10. The structure according to claim 8, wherein
the fourth nitride region includes a plurality of first films and a plurality of second films,
one of the plurality of first films is provided between one of the plurality of second films and another one of the plurality of second films,
the one of the plurality of second films is provided between the one of the plurality of first films and another one of the plurality of first films, and
an Al composition ratio in the plurality of first films is higher than an Al composition ratio in the plurality of second films.

11. The structure according to claim 1, wherein
the nitride member further includes a fourth nitride region including Al, Ga, and N,
the fourth nitride region is provided between the third nitride region and the semiconductor member,
the fourth nitride region includes a plurality of first films and a plurality of second films,
one of the plurality of first films is provided between one of the plurality of second films and another one of the plurality of second films,
the one of the plurality of second films is provided between the one of the plurality of first films and another one of the plurality of first films, and
an Al composition ratio in the plurality of first films is higher than an Al composition ratio in the plurality of second films.

12. The structure according to claim 10, wherein
a first film thickness of each of the plurality of first films is not less than 1 nm and less than 10 nm, and
a second film thickness of each of the plurality of second films is not less than 10 nm and not more than 50 nm.

13. The structure according to claim 8, wherein
the fourth nitride region is in contact with the third nitride region.

14. The structure according to claim 1, wherein
the base includes Si.

15. The structure according to claim 1, wherein
the first nitride region does not include carbon, or a concentration of carbon in the first nitride region is lower than a concentration of carbon in the second nitride region.

16. The structure according to claim 1, wherein
the semiconductor member includes a first semiconductor region and a second semiconductor region,
the first semiconductor region is provided between the nitride member and the second semiconductor region,
the first semiconductor region includes Al_{z1}Ga_{1-z1}N (0≤z1<1), and
the second semiconductor region includes Al_{z2}Ga_{1-z2}N (z1<z2<1).

17. The structure according to claim 16, wherein
the semiconductor member further includes a third semiconductor region,
the third semiconductor region is provided between the nitride member and the first semiconductor region,
the third semiconductor region includes Al_{z3}Ga_{1-z3}N (0≤z3<z2), and
the third semiconductor region includes carbon.

18. A semiconductor device, comprising:
a nitride structure according to claim 16;
a first electrode;
a second electrode; and
a third electrode,
a direction from the first electrode to the second electrode being along a second direction crossing the first direction,
a position of the third electrode in the second direction being between a position of the first electrode in the second direction and a position of the second electrode in the second direction,
the first semiconductor region including a first partial region, a second partial region, a third partial region, a fourth partial region, and a fifth partial region,
a direction from the first partial region to the first electrode being along the first direction,
a direction from the second partial region to the second electrode being along the first direction,
the third partial region being between the first partial region and the second partial region in the second direction, and a direction from the third partial region to the third electrode being along the first direction,
the fourth partial region being between the first partial region and the third partial region in the second direction,
the fifth partial region being between the third partial region and the second partial region in the second direction,
the second semiconductor region including a sixth partial region and a seventh partial region,
a direction from the fourth partial region to the sixth partial region being along the first direction, and
a direction from the fifth partial region to the seventh partial region being along the first direction.

19. The device according to claim 18, further comprising:
an insulating member,
at least a part of the insulating member being provided between the semiconductor member and the third electrode.

20. The device according to claim 18, wherein
at least a part of the third electrode is provided between the sixth partial region and the seventh partial region in the second direction.
